(19) United States
(12) Patent Application Publication
(10) Pub. No.: US 2026/0322076 A1
(43) Pub. Date: Oct. 15, 2026

(54) VERTICALLY EMITTING SEMICONDUCTOR LASER COMPONENT FOR OPTICAL DATA TRANSMISSION WITH AN OUTCOUPLING FACET WITH A MODE-SELECTIVE MACROSTRUCTURE AND A POLARIZATION-SELECTIVE MICROSTRUCTURE

(71) Applicant: TRUMPF PHOTONIC COMPONENTS GMBH, Ulm (DE)

(72) Inventors: Holger Joachim MÖNCH, BM Vaals (NL); Joseph PANKERT, Aachen (DE); Roger KING, Ulm (DE); Rashid SAFAISINI, Ulm (DE); Gunter LARISCH, Neuenhagen (DE)

(21) Appl. No.: 19/461,784

(22) Filed: Jan. 28, 2026

Related U.S. Application Data
(63) Continuation of application No. PCT/EP2024/070748, filed on Jul. 22, 2024.

(30) Foreign Application Priority Data
Jul. 31, 2023 (DE) 10 2023 120 245.6

(51) Int. Cl. H01S 5/183; H04B 10/50

(52) U.S. Cl. CPC H01S 5/18361; H04B 10/503

(57) ABSTRACT

A vertically emitting semiconductor laser component includes an upper Bragg mirror and a lower Bragg mirror. An active zone for generating laser radiation is arranged between the upper Bragg mirror and the lower Bragg mirror. The vertically emitting semiconductor laser component includes an upper outcoupling facet for the laser radiation, where the upper outcoupling facet includes both a mode-selective macrostructure and a polarization-selective microstructure.

### CROSS REFERENCE TO RELATED APPLICATIONS

This application is a continuation of International Application No. PCT/EP2024/070748 (WO 2025/026789 A1), filed on Jul. 22, 2024, and claims benefit to German Patent Application No. DE 10 2023 120 245.6, filed on Jul. 31, 2023. The aforementioned applications are hereby incorporated by reference herein.

### FIELD

The present invention relates to the field of optical communication technology, a vertically emitting semiconductor laser component, and a vertical-cavity surface-emitting laser (VCSEL) for optical data transmission.

### BACKGROUND

VCSELs for optical data transmission are also known as datacom VCSELs. One advantage of VCSELs is that they can offer the highest performance in data transmission with simultaneously little power consumption. In a VCSEL (vertical-cavity surface-emitting laser) laser diode, the light is emitted perpendicular to the plane of the semiconductor chip, in contrast to an edge-emitting laser diode, where the light exits at one or two edges of the chip.

US 10 742 000 B2 concerns an elliptical aperture VCSEL with reduced RIN (stochastic or relative intensity noise). According to the abstract, the VCSEL described therein comprises the following: an elliptical oxidation aperture in an oxidized region located between an active region and an emission surface, wherein the elliptical aperture has a short radius and a long radius with a radius ratio (short radius)/(long radius) between 0.6 and 0.8, wherein the VCSEL has a relative intensity noise (RIN) of less than -140 dB/Hz. The VCSEL can contain an elliptical emission aperture with the same dimensions as the elliptical oxidation aperture.

To reduce the RIN, the prior art therefore proposes providing an elliptical oxidation aperture or oxide aperture within the laser cavity.

### SUMMARY

In an embodiment, the present disclosure provides a vertically emitting semiconductor laser component includes an upper Bragg mirror and a lower Bragg mirror. An active zone for generating laser radiation is arranged between the upper Bragg mirror and the lower Bragg mirror. The vertically emitting semiconductor laser component includes an upper outcoupling facet for the laser radiation, where the upper outcoupling facet includes both a mode-selective macrostructure and a polarization-selective microstructure.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 is a first schematic representation of a plan view of an upper outcoupling facet with a mode-selective macrostructure as well as a polarization-selective microstructure for a vertically emitting semiconductor laser component;

FIG. 2 is a second schematic representation of a plan view of an upper outcoupling facet with a mode-selective macrostructure as well as a polarization-selective microstructure for a vertically emitting semiconductor laser component;

FIG. 3 is a schematic sectional view of a vertically emitting semiconductor laser component;

FIG. 4 is a schematic view of a chip with a vertically emitting semiconductor laser component;

FIG. 5 is a schematic view of a communication system; and

FIG. 6 is a flowchart of a method for production of a vertically emitting semiconductor laser component.

### DETAILED DESCRIPTION

An embodiment of the present disclosure provides an improved vertically emitting semiconductor laser component, in particular a VCSEL, for optical data transmission. An embodiment of the present disclosure provides a vertically emitting semiconductor laser component that allows high speeds in optical data transmission over a wide range of environmental conditions, in particular over a wide temperature range. An embodiment of the present disclosure provides a vertically emitting semiconductor laser component that can be manufactured economically or with simplified process steps and/or with high yield. An embodiment of the present disclosure improves the lifespan of datacom VCSELs with low RIN.

A first aspect of the present invention, provides a vertically emitting semiconductor laser component, in particular a VCSEL, with an upper Bragg mirror and a lower Bragg mirror, wherein an active zone for generating laser radiation is arranged between the upper Bragg mirror and the lower Bragg mirror; wherein the vertically emitting semiconductor laser component has an upper outcoupling facet for the laser radiation, wherein the upper outcoupling facet has both a mode-selective macrostructure and a polarization-selective microstructure.

According to a further aspect of the present invention, the use of a surface relief on an outcoupling facet of a VCSEL, wherein the surface relief of the outcoupling facet has a mode-selective macrostructure and a polarization-selective microstructure, is provided in a communication system for optical data transmission.

According to a further aspect of the present invention, a vertically emitting semiconductor laser component, in particular a VCSEL, having an upper Bragg mirror and a lower Bragg mirror, wherein an active zone for generating laser radiation is arranged between the upper Bragg mirror and the lower Bragg mirror; the vertically emitting semiconductor laser component has an upper outcoupling facet for the laser radiation, wherein the upper outcoupling facet has a polarization-selective microstructure, and the semiconductor laser component is configured to decrease in its light intensity by no more than 3dB compared to excitation at 1GHz under high frequency excitation up to a frequency of 25 GHz, in particular in the case of high-frequency excitation with a frequency of 25 GHz. Optionally, the upper outcoupling facet can have a mode-selective macrostructure. It is understood that the further features and embodiments described in connection with the first aspect within the framework of this disclosure can also be combined with this aspect.

Another aspect of the present invention includes a communication system with an input terminal for receiving data, a modulator and a vertically emitting semiconductor laser component, as mentioned above and/or described below.

A further aspect of the present invention includes a method for producing a vertically emitting semiconductor laser component, wherein the method has the following steps: providing a semiconductor substrate; depositing a layer sequence for a lower Bragg mirror on the semiconductor substrate; depositing an active layer with an active zone for generating laser radiation on the lower Bragg mirror; depositing a layer sequence for an upper Bragg mirror on the active layer; providing an upper outcoupling facet for the laser radiation on the upper Bragg mirror, wherein the upper outcoupling facet has both a mode-selective macrostructure as well as a polarization-selective microstructure.

A further aspect of the present invention includes a method for producing a vertically emitting semiconductor laser component, wherein the method has the following steps: providing a semiconductor substrate; depositing a layer sequence for a lower Bragg mirror on the semiconductor substrate; depositing an active layer with an active zone for generating laser radiation on the lower Bragg mirror; depositing a layer sequence for an upper Bragg mirror on the active layer; providing an upper outcoupling facet for the laser radiation on the upper Bragg mirror, wherein the upper outcoupling facet has a polarization-selective microstructure and the semiconductor laser component, under high frequency excitation up to a frequency of 25GHz, in particular under high frequency excitation of 25GHz, is configured to have a light intensity that does not decrease by more than 3dB compared to excitation at 1GHz.

It is understood that optionally further layers can be provided, which may also be arranged between the aforementioned layers, for example, one or more optional current aperture(s) between the active layer and the upper and/or lower Bragg mirror.

VCSELs in datacom applications are often operated at relatively high currents with high-frequency signal modulation. The required output power is primarily achieved in multimodal operation with conventional VCSELs. This can lead to competition and degeneration of the many modes, which can cause strong noise (relative intensity noise (RIN)). Even with a reduced number of modes, a similar contribution to noise can occur due to operation with unstable polarization. This regularly results in so-called “flips” of the polarization direction. Furthermore, conventional solutions have the problem that they sometimes only allow an improvement in RIN for a narrow range of operating parameters, but not over a wide range of operating parameters and in particular not over a wide temperature range. Furthermore, solutions such as the VCSEL described in the aforementioned US 10,742,000 B2, with its elliptical current aperture arranged within the layer sequence of the semiconductor at the active layer, can be susceptible to process variations in semiconductor production. Furthermore, the current flow within the semiconductor can vary for the specific application of datacom VCSELs over the desired wide current and temperature range.

One aspect of the present invention provides an optical solution with a specially formed upper outcoupling facet of the vertically emitting semiconductor laser component, wherein the upper outcoupling facet has both a mode-selective macrostructure as well as a polarization-selective microstructure. According to one aspect, the present disclosure reduces the number of competing modes and simultaneously stabilizes the polarization. This is achieved by using a surface structure, in particular a surface relief, of the outcoupling facet of the VCSEL, which has a spatial macrostructure and a polarization-selective structure. In the simplest case, a datacom VCSEL with an elliptically bordered relief structure can be provided with a polarization grid.

The coexistence of plurality of modes in a VCSEL is a source of noise. A lateral macrostructure with dimensions of typical VCSEL modes can favor or hinder individual modes, and thereby reduce the number of modes and the noise. For example, very small macrostructures (a few µm) can be used to force operation on a fundamental mode, which has a smaller diameter than higher-order modes. Similarly, elliptical cross-sections favor modes with a larger extent along the long semi-axis.

The embodiment of the upper outcoupling facet, wherein the upper outcoupling facet has both a mode-selective macrostructure as well as a polarization-selective microstructure, has the advantage that an improvement in the RIN can be achieved using purely optical means. This solution provides an advantageous noise performance over a wide temperature range. Even over a large current range, it is possible to prevent the VCSEL from operating in an unstable polarization range under certain operating conditions, and at the same time, operation in desired laser modes can be ensured, in particular at the high modulation frequencies required for datacom VCSELs.

Unlike the current aperture described in the aforementioned US 10,742,000 B2, a structure on the upper side of the outcoupling mirror has a purely optical function. The upper side of the upper Bragg mirror or outcoupling mirror can be described as a outcoupling facet. The outcoupling side DBR of the VCSEL usually terminates in a belly of the standing wave field against air or a refracting medium. For example, if the layer thickness of the DBR is increased by a quarter of the wavelength in the medium, the reflectivity of the DBR is therefore significantly reduced, and laser work is more difficult. However, if the additional layer thickness is partially removed, the full reflectivity is restored in the back-etched region, for example. This favors modes that have high intensity in these regions. A structure on the upper side is easily accessible and therefore practical to implement. It is understood, however, that one or more layers of the upper Bragg mirror can also be considered part of the upper outcoupling facet.

The terms macrostructure and microstructure describe the relative relationship, wherein the mode-selective macrostructure has a larger structure size than the polarization-selective microstructure. Alternatively, one can also speak of a first mode-selective structure of the outcoupling facet and a second polarization-selective structure of the outcoupling facet. The polarization-selective macrostructure of the outcoupling facet is a structure which is configured to favor a limited number of laser modes, in particular wherein the mode-selective macrostructure is configured to favor a single laser mode. The polarization-selective microstructure is a structure that is configured to promote polarization of the laser radiation. For example, the polarization-selective microstructure can be implemented as a grid or as an optical metastructure.

According to one aspect of the present invention, the upper outcoupling facet can have a polarization-selective microstructure, and the semiconductor laser component is configured to decrease in its light intensity by no more than 3dB compared to excitation at 1GHz under high frequency excitation up to a frequency of 25GHz. One advantage can be that, thanks to the small drop in light intensity under high frequency excitation at 25GHz compared to excitation at 1GHz, upstream amplifier electronics can have a simpler design; in particular, modulation frequency-selective gain matching can be omitted or at least simplified.

All features of the subjects described herein and also of the claimed subjects are usable both in isolation and in combination with each other, are compatible with each other and provided and usable for further development with each other, provided that no logical contradiction arises, and are hereby accordingly disclosed. In the following, any reference to a subject or feature (including the indefinite articles “a” and “an” and the definite articles “the,” “a,” “a”), two subjects or two features, or any other number of subjects or features, unless expressly stated otherwise or a logical contradiction arises, shall be understood as meaning that the existence of further such subjects and features is not excluded by the present disclosure, but is also included by the present disclosure.

In one embodiment, the outcoupling facet with the mode-selective macrostructure and the polarization-selective microstructure can be a (purely) optical structure which is arranged on an upper side of the upper Bragg mirror. One advantage of this embodiment can be that a structure on the upper side is easily accessible and therefore practical to implement. Another advantage can be that different mode profiles and/or presentations can be easily adapted to customer requirements since only the output facet needs to be adjusted, not however the entire layer structure of the semiconductor. An existing layer structure of the semiconductor with an upper Bragg mirror, lower Bragg mirror and the active region in between can therefore be reused for various applications. This allows for simple and economical production. The upper side of the upper Bragg mirror can be considered to be the side which is located in the beam direction of the laser beam in the direction in which the laser radiation is coupled out of the semiconductor laser component.

The outcoupling facet can be formed as an (optical) relief structure. The mode-selective macrostructure of the outcoupling facet can have a first region with a first layer thickness. The mode-selective microstructure of the outcoupling facet can have a second region with a second layer thickness, in particular wherein the second layer thickness is smaller than the first layer thickness. A difference in layer thickness, or an additional layer thickness and back-etching, can occur in a semiconductor material of the VCSEL, for example in the top layer made of Gallium Arsenide (GaAs). Alternatively or additionally, a dielectric layer can be applied and then structured. Alternatively or additionally, a dielectric layer stack can be applied, in which one layer is selectively etched. The structuring can be done lithographically, e.g., via e-beam lithography, Ultraviolet (UV) lithography or nanoimprint lithography.

The mode-selective macrostructure can be configured to favor a limited number of laser modes. In particular, the mode-selective macrostructure can be configured to favor a single laser mode. In particular, the macrostructure may be configured to adapt the lateral mode structure. One advantage of this embodiment can be considered that the emission behavior of the semiconductor laser component can be adjusted to a desired application. It is understood that a favored mode does not necessarily have to be a basic mode used in “single mode” VCSELs, but can be any higher-order mode.

The mode-selective macrostructure can have a first region with a first reflectivity and a second region with a second reflectivity that differs from the first reflectivity. The outcoupling facet can be correspondingly provided with a tailored reflectivity to favor desired modes.

The mode-selective macrostructure of the outcoupling facet can have a relief with a non-rotationally symmetric contour. The mode-selective macrostructure of the outcoupling facet can have a relief with an oval contour, in particular with an elliptical contour. A corresponding relief structure makes it possible to reduce the number of competing modes and, in particular, to favor modes whose geometric dimensions fit the non-rotationally symmetric contour, in particular the oval or elliptical relief contour. For example, the relief with the oval contour can have an inner oval region with a smaller layer thickness as well as an outer region surrounding it with a larger layer thickness. This accordingly applies to other non-rotationally symmetric or elliptical contours.

In a further development, the mode-selective macrostructure of the outcoupling facet can have a non-rotationally symmetric or oval relief with a constriction. In particular, the mode-selective macrostructure can have a figure-eight contour. This is a particularly advantageous example, wherein, thanks to the oval contour with a constriction, in particular with a figure-eight contour, other modes can be favored instead of or alongside the basic mode, but not an uncontrolled high number of modes, rather a limited number. The mode profile can therefore be advantageously adjusted to a desired application.

The mode-selective macrostructure cannot be formed rotationally symmetric in a plane parallel to layers of the upper Bragg mirror. The mode-selective macrostructure may be configured to overcome degeneration of modes. One advantage of this embodiment with a non-rotationally symmetric macrostructure is that it can counteract degeneration of modes. One advantage of this embodiment is that the emission behavior of the laser can be further stabilized. Unwanted switching between different emission modes can be reduced. This can improve noise performance.

The polarization-selective microstructure can have a grid structure for polarizing the laser light. In other words, a surface grid for polarizing the light can be arranged on the output facet. However, not in isolation, but in conjunction with a mode-selective macrostructure. The mode-selective macrostructure and the polarization-sensitive microstructure can work together advantageously or create a synergistic effect. In particular, this combination has proven to be particularly advantageous for stabilization over a wide temperature range.

The polarization-selective microstructure can have a structure size smaller than the laser wavelength of the laser light. For example, a grid structure with a grid spacing or grid period smaller than the laser wavelength can be provided. However, an optical metastructure with structures smaller than the laser wavelength can also be provided. One advantage of this embodiment is that, with this choice of structure sizes of the polarization-selective microstructure, losses can be reduced by avoiding diffraction.

The mode-selective macrostructure and the polarization-selective microstructure can together be formed as an elliptically shaped surface relief with a grid structure enclosed by the surface relief. For example, an elliptical depression of the outcoupling facet can be provided as the optical macrostructure, and this depressed region can have a polarization-selective grid structure. It goes without saying that instead of a depression, an increase or other influence on the reflection behavior can also be provided. Generally speaking, the upper outcoupling facet can have a macrostructure, which in turn contains a fine structure. Here, the macrostructure defines spatially lateral modes, while the fine structure determines the polarization. An example is an oval or circular structure with, for example, a diameter of 10 µm and a grid with, for example, a pitch of 150 nm.

The mode-selective macrostructure and the polarization-selective microstructure can be formed by an optical metastructure of the outcoupling facet, in particular wherein the outcoupling facet has an optical metastructure a structure with spatially varying phase matching. The metastructure on the outcoupling facet can substantially correspond to the mode pattern of a preferred mode. Corresponding optical metastructures can be determined, for example, by means of numerical simulations.

The optical metastructure can be configured to provide a varying effective refractive index. Alternatively or additionally, the optical metastructure can have a varying density of turrets of constant height and an extent smaller than the wavelength. For example, by giving the individual turrets an elongated shape, the polarization can be selected. Providing an optical metastructure with varying density but the same height in the emission direction of the VCSEL laser radiation can be particularly advantageous since this can be provided by structuring a layer with a defined height. A layer to be structured can be provided in semiconductor production or the production of a wafer. The structuring can be done using known semiconductor production methods. This allows efficient and economical production with high quality. Another advantage of a metastructure over a relief with a hard step or relief edge can be the avoidance of diffraction at the edge of the relief, which can cause losses. Another advantage can be that a more precise adaptation to a desired intensity profile of certain modes can be achieved, and therefore improved selectivity or stability.

The vertically emitting semiconductor laser component can have (at least) one current aperture, wherein the current aperture in a plane orthogonal to a beam direction of the laser beam has a larger diameter than a diameter of the mode-selective macrostructure of the outcoupling facet with the polarization-selective microstructure. In other words, the diameter, measured in a plane parallel to layers of the upper Bragg mirror, can lie orthogonal to the beam direction of the laser beam. Since the current aperture or current apparatus is larger than the relief structure or mode-selective macrostructure, the current density within the VCSEL can be reduced. The current can spread electrically over a larger region within the semiconductor. In this case, mode selection does not occur, or at least not solely, through the current aperture. Rather, optical mode selection occurs through the macrostructure of the outcoupling facet in conjunction with the polarization-selective microstructure of the outcoupling facet. One advantage of this embodiment can be that the definition of the current aperture, e.g. by an oxide aperture, implantation or buried tunnel diode, can be independent of the optical structure of the outcoupling facet described herein. It is not necessary for the current aperture to exactly match the optical structure or mode. Lateral transport of charge carriers, for example in quantum wells of an active zone, also contributes current injection for amplification which occurs approximately 1 µm or a few µm offset from the mode. This can be advantageously exploited in that current injection is over the entire surface and over a slightly larger region than would correspond to (optical) mode selection. This allows the current to be conducted in a larger diameter despite a selected, spatially narrow mode. The current density is thereby reduced, and a significantly increased lifespan can thereby result. This can provide a significant advantage over mode selection using an elliptical current aperture.

The vertically emitting semiconductor laser component can be a VCSEL for optical data transmission. A VCSEL for optical data transmission can also be called a datacom VCSEL. An embodiment of the present disclosure with the specific outcoupling facet, which has both a mode-selective macrostructure and a polarization-selective microstructure, is particularly advantageous for VCSELs for optical data transmission. Datacom VCSELs are often operated over a wide temperature range, which results in special demands that do not arise in other applications or in purely research setups under laboratory conditions.

In one embodiment of the present disclosure, the vertically emitting semiconductor laser component has a relative intensity noise (RIN) of less than -80 dB/Hz, in particular less than -100 dB/Hz, in particular less than -120 dB/Hz, in particular less than -140 dB/Hz. This allows particularly high data transmission rates in optical communication systems. The indicated values can be relative intensity noise (RIN) in a frequency range up to 40 GHz, in particular in a range between 1 GHz and 40 GHz, in particular in a range between 2 GHz and 30 GHz, and in particular in a range between 5 GHz and 25 GHz.

The vertically emitting semiconductor laser component can be configured is configured to decrease in its light intensity by no more than 3dB compared to excitation at 1GHz under high frequency excitation up to a frequency of 25GHz. This makes the vertically emitting semiconductor laser component particularly advantageous for optical data transmission. One advantage can be that, thanks to the small drop in light intensity under high frequency excitation at 25GHz compared to excitation at 1GHz, upstream amplifier electronics can have a simpler design; in particular, modulation frequency-selective gain matching can be omitted or at least simplified.

A particularly advantageous use of the proposed vertically emitting semiconductor laser component is the use in a communication system for optical data transmission. The communication system or a transmitter for an optical communication system can include an input terminal for receiving data, a modulator and a vertically emitting semiconductor laser component. An input terminal can be understood as an interface for receiving data. The received data can be converted by the modulator and, for example, modulated onto the laser light emitted by the vertically emitting semiconductor laser component, for example in the form of current modulation or voltage modulation. The communication system can also have a receiver with a detector for detecting the modulated laser light as well as a demodulator which is configured to demodulate the detected laser light and convert it into data that can be output via an interface for outputting data.

The advantages and optional further features described above in detail for the first aspect of the invention apply accordingly to the further aspects of the invention.

It is understood that the features mentioned above and those to be explained below can be used not only in the combination specified in each case but also in other combinations or on their own without departing from the scope of the present disclosure.

Exemplary embodiments of aspects of the invention are shown in the drawings and are explained in more detail in the following description.

The same reference signs used in the figures denote identical or at least equivalent elements. The terms “top,” “bottom,” “left” and “right,” as well as direction-dependent information derived therefrom such as “upper side” refer to the writing/reading direction of the figure designation “Fig.” belonging to a drawing, which is printed on the drawing plane below the drawing. The horizontal direction is parallel to the writing direction of “Fig.” and the vertical direction is perpendicular to the writing direction of “Fig.” The writing direction is based on horizontal right-to-left writing, i.e., primarily from left to right, as in Latin, English, and German, for example.

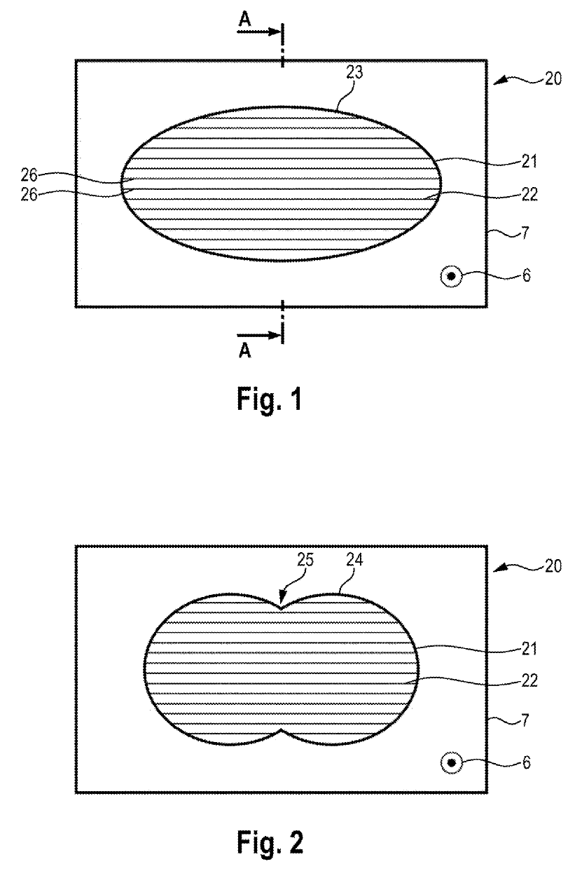

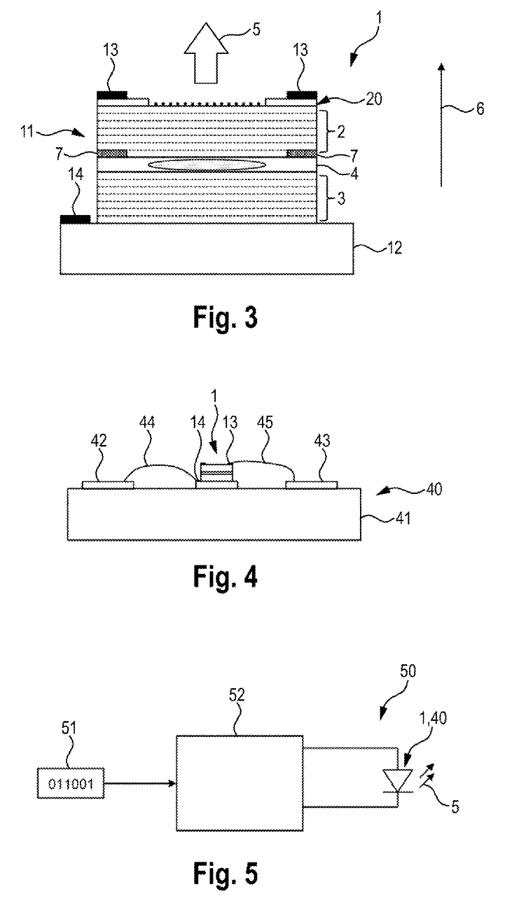

FIGS. 1 and 2 each show schematic views of a plan view of an upper outcoupling facet with a mode-selective macrostructure as well as a polarization-selective microstructure for a vertically emitting semiconductor laser component. FIG. 3 shows a schematic sectional view of a vertically emitting semiconductor laser component, from which an exemplary layer structure can be seen. FIGS. 1 to 3 are described together below.

The vertically emitting semiconductor laser component 1 shown in FIG. 3 is a VCSEL. The vertically emitting semiconductor laser component 1 has an upper Bragg mirror 2 and a lower Bragg mirror 3. An active zone 4 for generating laser radiation 6 is arranged between the upper Bragg mirror 2 and the lower Bragg mirror 3. The basic structure of a VCSEL is known to a person skilled in the art. The Bragg mirrors can each have layer sequences with different refractive indices and provide a resonator or a laser cavity for the laser radiation generated in the active zone 4. The upper Bragg mirror is formed as a partially transparent mirror through which the laser radiation 5 can be coupled out in a light emission direction 6. The light emission direction 6 is shown in FIGS. 1 to 3 by the arrow 6.

In the shown exemplary embodiment, the vertically emitting semiconductor laser component 1 is shown with a mesa 11 on a substrate 12. It is understood that the present disclosure is not limited to a mesa structure and that other embodiments of the semiconductor laser component 1 can also be provided. For example, a planar configuration with one or more semiconductor laser components 1 can be provided, in particular an array of several semiconductor laser components 1. Several semiconductor laser components 1 can preferably be separated from each other by trenches, for example to avoid crosstalk.

For electrical contacting, as shown in the sectional view in FIG. 3, an upper connection contact 13, also referred to as top contact, and a lower connection contact 14, also referred to as bottom contact or substrate contact, can be provided. The upper connection contact 13 can, for example, be formed as an electrode that is at least partially ring-shaped or C-shaped.

As shown in FIG. 3, the vertically emitting semiconductor laser component 1 has an upper outcoupling facet 20 for the laser radiation 5, wherein the upper outcoupling facet 20 has both a mode-selective macrostructure 21 as well as a polarization-selective microstructure 22. Exemplary embodiments of the upper outcoupling facet 20 are shown in the plan views in FIGS. 1 and 2. The shown outcoupling facet 20, with the mode-selective macrostructure 21 and the polarization-selective microstructure 22 is an optical structure which is arranged on an upper side of the upper Bragg mirror 2.

The mode-selective macrostructure 21 is formed to favor a limited number of laser modes, in particular a single laser mode. An exemplary geometry with which a single laser mode can be favored is shown in the plan view in FIG. 1. However, it is also possible to choose a geometry with which a limited number of several laser modes is favored. An example is shown in the plan view in FIG. 2.

In the exemplary embodiment shown in FIG. 1, the mode-selective macrostructure 21 of the outcoupling facet 20 is formed as a relief with an oval contour 23, in particular with an elliptical contour. This allows the lateral extent of the modes to be easily precisely adjusted to a desired mode profile using an optical layer.

In the exemplary embodiment shown in FIG. 2, the mode-selective macrostructure 21 of the outcoupling facet 20 has an oval relief 24 with a constriction 25. In particular, the mode-selective macrostructure 21 can have a figure-eight contour, as shown in FIG. 2 with the outline of a reclining eight.

In the exemplary embodiments shown in FIGS. 1 and 2, an inner region, i.e., a region lying within the contours 23 or 24, and an outer region, i.e., a region lying outside the contours 23 or 24, can, for example, have different layer thicknesses and thus, adjacent to the upper Bragg mirror 2, have different layer thicknesses and/or different reflectivities and therefore influence lateral mode propagation. As shown in the sectional view in FIG. 3, for example, the layer thickness can be reduced within the contours 23, 24. The relief with the oval contour can therefore have an inner oval region with a smaller layer thickness as well as an outer region surrounding it with a larger layer thickness. The sectional view in FIG. 3 can be considered, with respect to the upper outcoupling facet, as a section along the line AA in FIG. 1.

The additional layer thickness and back-etching can occur in the semiconductor material of the VCSEL, e.g. in the top layer made of GaAs. Alternatively, a dielectric layer can be applied and then structured. Alternatively, a dielectric layer stack can be applied, in which one layer is selectively etched. The structuring occurs lithographically, e.g. via e-beam lithography, UV lithography or nano-imprint lithography.

As shown in the plan views in FIG. 1 and 2, the mode-selective macrostructure 21 is preferably non-rotationally symmetric in a plane parallel to the layers of the upper Bragg mirror 2 (and thus in FIG. 1 and 2 parallel to the plane of the age of the drawing) and is configured to overcome a degeneration of modes. This allows the RIN of the emitted laser radiation from the semiconductor laser component to be further reduced.

In the exemplary embodiments shown in FIGS. 1 to 3, the contour 23, 24 of the mode-selective macrostructure surrounds the region with the polarization-selective microstructure 22. In the illustrated, non-restrictive exemplary embodiments, the polarization-selective microstructure is formed as a grid structure for polarizing the laser light. In this case, the polarization-selective microstructure has a structure size smaller than a laser wavelength of the laser light. The grid structure 26 can be provided, for example, by using lithographic methods to provide a plurality of parallel ridges in the upper outcoupling facet 20 of the semiconductor laser component. A grid period or a distance between adjacent ridges is preferably smaller than the wavelength of the laser radiation. This can prevent or reduce scattering losses. The mode-selective macrostructure 21 and the polarization-selective microstructure 22 are together formed as an elliptically shaped surface relief with an enclosed grid structure.

As shown in the sectional view in FIG. 3, the vertically emitting semiconductor laser component can optionally have a current aperture 7. In the shown exemplary embodiment, the current aperture is arranged between the active layer 4 and the upper Bragg mirror 2. However, other arrangements in the layer structure are also conceivable. One special feature is that the current aperture 7 in a plane orthogonal to a beam direction 6 of the laser beam 5 has a larger diameter than a diameter of the mode-selective macrostructure 21 of the outcoupling facet 20 with the polarization-selective microstructure 22. The size of the current aperture 7 is shown in plan view in FIGS. 1 and 2 and is larger than the mode-selective macrostructure 21, wherein a rectangular current aperture 7 is provided by way of example. Thus, a lateral favoring of desired modes is more narrowly limited by the mode-selective macrostructure 21 of the outcoupling facet, i.e. by variation of the optical properties instead of by a constriction through a current aperture 7. Since the current aperture or current apparatus is larger than the relief structure or mode-selective macrostructure, the current density within the VCSEL can be reduced. The current can spread electrically over a larger region within the semiconductor. In this case, mode selection does not occur, or at least not solely, through the current aperture. Rather, optical mode selection occurs through the macrostructure of the outcoupling facet in conjunction with the polarization-selective microstructure of the outcoupling facet. One advantage of this embodiment can be that the definition of the current aperture, e.g. by an oxide aperture, implantation or buried tunnel diode, can be independent of the optical structure of the outcoupling facet described herein. It is not necessary for the current aperture to exactly match the optical structure or mode. Lateral transport of charge carriers, for example in quantum wells of an active zone, also contributes current injection for amplification which occurs approximately 1 µm or a few µm offset from the mode. This can be advantageously exploited in that current injection is over the entire surface and over a slightly larger region than would correspond to (optical) mode selection. This allows the current to be conducted in a larger diameter despite a selected, spatially narrow mode. The current density is thereby reduced, and a significantly increased lifespan can thereby result.

It is understood that the choice of the exact structure is relatively free and should follow typical lateral mode structures. These can be combined with a (slightly) differently shaped current aperture. Simple examples are: (a) a circular current aperture with an elliptical or annular facet; (b) a substantially oval facet, possibly with an additional constriction; (c) a rectangular current aperture with an elliptical facet or a facet with multiple maxima, as shown by way of example in FIG. 1 and FIG. 2; (d) a circular or rectangular current aperture with a metastructure on the outcoupling facet which substantially corresponds to the mode pattern of a preferred mode.

In another variation of the vertically emitting semiconductor laser component 1 shown in FIG. 3, the mode-selective macrostructure is an optional feature. The vertically emitting semiconductor laser component 1 can be a VCSEL with an upper Bragg mirror 2 and a lower Bragg mirror 3, wherein an active zone 4 for generating laser radiation 5 is arranged between the upper Bragg mirror 2 and the lower Bragg mirror 3. The vertically emitting semiconductor laser component 1 has an upper outcoupling facet 20 for the laser radiation 5. The upper outcoupling facet 20 has a polarization-selective microstructure 22. The semiconductor laser component 1, under high frequency excitation up to a frequency of 25GHz, in particular under high frequency excitation of 25GHz, is configured to have a light intensity that does not decrease by more than 3dB compared to excitation at 1GHz.

FIG. 4 shows a schematic view of a chip 40 with a vertically emitting semiconductor laser component 1. The chip 40 has a carrier 41 on which the semiconductor laser component 1 is arranged. Connection contacts 42, 43 can be provided, which are connected to the respective electrical connection contacts 13, 14 of the semiconductor laser component 1 by means of bond wires 44, 45. The provision of such a chip facilitates the handling of the vertically emitting semiconductor laser component 1. Optionally, the chip 40 can have additional functional elements, such as an amplifier, a modulator, or protection circuits, such as ESD protection elements.

FIG. 5 shows a schematic view of a communication system or a transmitter for an optical communication system 50. The communication system or a transmitter for an optical communication system has an input terminal 51 for receiving data, a modulator 52 and a vertically emitting semiconductor laser component 1 or a chip 40 with such a laser. As described at the beginning, an input terminal 51 can be understood as an interface for receiving data. The received data can be converted by the modulator 52 and, for example, modulated onto the laser light 5 emitted by the vertically emitting semiconductor laser component 1 in the form of current modulation or voltage modulation. The communication system can also have a receiver with a detector for detecting the modulated laser light as well as a demodulator which is configured to demodulate the detected laser light and convert it into data that can be output via an interface for outputting data.

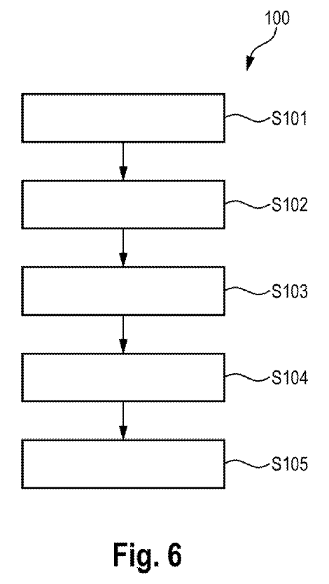

FIG. 6 shows a flowchart of a method 100 for production of a vertically emitting semiconductor laser component. In a first step S101, a semiconductor substrate 12 is provided. In a second step S102, a layer sequence for a lower Bragg mirror is deposited on the semiconductor substrate. In a third step, S103, an active layer with an active zone for generating laser radiation is deposited on the lower Bragg mirror. In a fourth step S104, a layer sequence for an upper Bragg mirror is deposited on the active layer. In a first variant of a method for producing of a method for producing a vertically emitting semiconductor laser component, in a fifth step S105, an upper outcoupling facet for the laser radiation is provided on the upper Bragg mirror, wherein the upper outcoupling facet has both a mode-selective macrostructure as well as a polarization-selective microstructure. Such an outcoupling facet can be provided by applying further layers and structuring them, or by structuring one or more existing layers such as upper layers of the upper Bragg mirror. In a second variant of a method for producing of a method for producing a vertically emitting semiconductor laser component, in a fifth step S105 an upper outcoupling facet for the laser radiation is provided on the upper Bragg mirror, wherein the upper outcoupling facet has both a polarization-selective microstructure, and wherein the semiconductor laser component is configured to decrease in its light intensity by no more than 3dB compared to excitation at 1GHz under high frequency excitation up to a frequency of 25GHz.

According to one embodiment of the present disclosure, an elliptically shaped surface relief with a grid structure can be applied to reduce noise (RIN) in datacom VCSELs. The number of modes can be reduced, and regions of unstable polarization can be avoided over a wide temperature and current range. Scattering losses can be avoided by dimensioning the grid structure smaller than the wavelength. Grids can also be formed as optical metastructures.

In summary, advantages of one or more aspects of the present invention can be in particular that a further improved or alternative vertically emitting semiconductor laser component, in particular VCSEL, can be provided for optical data transmission. One advantage can be that a vertically emitting semiconductor laser component can be provided which allows high speeds in optical data transmission over a wide range of environmental conditions, in particular over a wide temperature range. Alternatively or additionally, an advantage can be that a vertically emitting semiconductor laser can be provided, which can be manufactured economically or with simplified process steps and/or with high yield. Alternatively or additionally, an advantage can be that a vertically emitting semiconductor laser can be provided which improves the lifespan of datacom VCSELs with low RIN.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A vertically emitting semiconductor laser component, comprising:
an upper Bragg mirror; and
a lower Bragg mirror, wherein an active zone for generating laser radiation is arranged between the upper Bragg mirror and the lower Bragg mirror,
wherein the vertically emitting semiconductor laser component comprises an upper outcoupling facet for the laser radiation, and wherein the upper outcoupling facet comprises both a mode-selective macrostructure and a polarization-selective microstructure.

2. The vertically emitting semiconductor laser component according to claim 1, wherein the upper outcoupling facet with the mode-selective macrostructure and the polarization-selective microstructure is an optical structure which is arranged on an upper side of the upper Bragg mirror.

3. The vertically emitting semiconductor laser component according to claim 1, wherein the upper outcoupling facet is formed as a relief structure, wherein the mode-selective macrostructure of the upper outcoupling facet has a first region with a first layer thickness, and wherein the mode-selective microstructure of the upper outcoupling facet has a second region with a second layer thickness.

4. The vertically emitting semiconductor laser component according to claim 1, wherein the mode-selective macrostructure is configured to favor a limited number of laser modes.

5. The vertically emitting semiconductor laser component according to claim 1, wherein the mode-selective macrostructure has a first region with a first reflectivity and a second region with a second reflectivity that differs from the first reflectivity.

6. The vertically emitting semiconductor laser component according to claim 1, wherein the mode-selective macrostructure of the upper outcoupling facet has a relief with a non-rotationally symmetric contour.

7. The vertically emitting semiconductor laser component according to claim 1, wherein the mode-selective macrostructure of the upper outcoupling facet has an oval relief with a constriction.

8. The vertical emitting semiconductor laser component according to claim 1, wherein the mode-selective macrostructure is non-rotationally symmetric in a plane parallel to layers of the upper Bragg mirror and is configured to overcome degeneration of modes.

9. The vertically emitting semiconductor laser component according to claim 1, wherein the polarization-selective microstructure has a grid structure for polarizing a laser light.

10. The vertically emitting semiconductor laser component according to claim 1, wherein the polarization-selective microstructure has a structure size smaller than a laser wavelength of a laser light.

11. The vertically emitting semiconductor laser component according to claim 1, wherein the mode-selective macrostructure and the polarization-selective microstructure are together formed as an elliptically shaped surface relief with an enclosed grid structure.

12. The vertically emitting semiconductor laser component according to claim 1, wherein the mode-selective macrostructure and the polarization-selective microstructure are formed by an optical metastructure of the upper outcoupling facet.

13. The vertically emitting semiconductor laser component according to claim 12, wherein the optical metastructure is configured to provide a varying effective refractive index, wherein the optical metastructure has a varying density of turrets of constant height and an extent smaller than a wavelength.

14. The vertically emitting semiconductor laser component according to claim 1, wherein the vertically emitting semiconductor laser component further comprises a current aperture, wherein the current aperture in a plane orthogonal to a beam direction of a laser beam has a larger diameter than a diameter of the mode-selective macrostructure of the upper outcoupling facet with the polarization-selective microstructure.

15. The vertically emitting semiconductor laser component according to claim 1, wherein the vertically emitting semiconductor laser component is a VCSEL for optical data transmission.

16. The vertically emitting semiconductor laser component according to claim 1, wherein the vertically emitting semiconductor laser component comprises a relative intensity noise (RIN) of less than -80 dB/Hz.

17. The vertically emitting semiconductor laser component according to claim 1, wherein the vertically emitting semiconductor laser component is configured to decrease in its light intensity by no more than 3dB compared to excitation at 1GHz under high frequency excitation up to a frequency of 25GHz.

18. A vertically emitting semiconductor laser component, comprising:
an upper Bragg mirror; and
a lower Bragg mirror, wherein an active zone for generating laser radiation is arranged between the upper Bragg mirror and the lower Bragg mirror,
wherein the vertically emitting semiconductor laser component comprises an upper outcoupling facet for the laser radiation, wherein the upper outcoupling facet comprises a polarization-selective microstructure, and wherein the vertically emitting semiconductor laser component is configured to decrease in its light intensity by no more than 3dB compared to excitation at 1GHz under high frequency excitation up to a frequency of 25GHz.

19. A communication system comprising:
an input terminal for receiving data;
a modulator; and
a vertically emitting semiconductor laser component according to claim 1.

20. A method for production of a vertically emitting semiconductor laser component, the method comprising:
providing a semiconductor substrate;
depositing a layer sequence for a lower Bragg mirror on the semiconductor substrate;
depositing an active layer with an active zone for generating laser radiation on the lower Bragg mirror;
depositing a layer sequence for an upper Bragg mirror on the active layer; and
providing an upper outcoupling facet for the laser radiation on the upper Bragg mirror, wherein the upper outcoupling facet comprises both a mode-selective macrostructure and a polarization-selective microstructure.

21. A method for production of a vertically emitting semiconductor laser component, the method comprising:
providing a semiconductor substrate;
depositing a layer sequence for a lower Bragg mirror on the semiconductor substrate;
depositing an active layer with an active zone for generating laser radiation on the lower Bragg mirror;
depositing a layer sequence for an upper Bragg mirror on the active layer; and
providing an upper outcoupling facet for the laser radiation on the upper Bragg mirror, wherein the upper outcoupling facet comprises a polarization-selective microstructure, and wherein the vertically emitting semiconductor laser component is configured to decrease in its light intensity by no more than 3dB compared to excitation at 1GH
